(19) United States
(12) Patent Application Publication
(10) Pub. No.: US 2026/0223560 A1
(43) Pub. Date: Jul. 30, 2026

(54) DISPLAY APPARATUS

(71) Applicant: LG Display Co., Ltd., Seoul (KR)

(72) Inventors: Jeongmin PARK, Paju-si (KR); Seonghwan WOO, Paju-si (KR)

(73) Assignee: LG Display Co., Ltd., Seoul (KR)

(21) Appl. No.: 19/447,633

(22) Filed: Jan. 13, 2026

(30) Foreign Application Priority Data
Jan. 24, 2025 (KR) 10-2025-0011720

(51) Int. Cl. H10K 59/131; H10K 59/124; H10K 77/10; H10K 102/00

(52) U.S. Cl. CPC H10K 59/131; H10K 59/124; H10K 77/111; H10K 2102/311

(57) ABSTRACT

A display apparatus includes a substrate having an active area in which an image is displayed and a bending area positioned at one side of the active area and having a curvature. At least one first connection line is disposed directly on an upper surface of the substrate in the bending area. A first planarization layer is disposed on the first connection line. At least one second connection line is disposed on the first planarization layer and is connected to the at least one first connection line through the first planarization layer.

### CROSS-REFERENCE TO RELATED APPLICATION

The present application claims priority to Korean Patent Application No. 10-2025-0011720, filed January 24, 2025, the entire contents of which is incorporated herein for all purposes by this reference.

### BACKGROUND

### Technical Field

The present specification relates to a display apparatus.

### Description of the Related Art

Display apparatuses are applied to various electronic devices such as TVs, mobile phones, notebooks, tablets, etc.

Examples of display apparatuses include organic light-emitting diode (OLED) display apparatuses that emit light by itself, liquid crystal display (LCD) devices that require a separate light source, etc.

A bezel area of the display apparatus is a factor that reduces aesthetics and immersion by being recognized by a user. Recently, narrow bezel display apparatuses with reduced bezel area in which an image is not displayed in the display apparatus are in the spotlight.

### BRIEF SUMMARY

A bezel area of a display apparatus may be reduced bending a bending area of a non-active area of a display panel formed on a flexible substrate and positioning a pad area of the non-active area on a back surface of an active area. Connection lines for electrically connecting the active area to a pad area may be disposed in a bending area of the display panel, and organic materials covering the connection lines may be disposed.

Due to a curvature of the bending area of the display panel, a tensile stress may be applied to the connection lines in the bending area, and thus cracks may occur in the connection lines in the bending area. In particular, the greatest tensile stress may be applied to the connection lines in an area with the greatest curvature, that is, an area with the smallest curvature radius, in the bending area, and cracks may occur in the connection lines.

The described display apparatus reduces tensile stress and prevents cracks in connection lines within the bending area by removing the intermediate inorganic substrate layer in the region that experiences the smallest curvature radius. A groove may also be formed in the upper polymer substrate layer so that the first connection line can be positioned closer to the neutral bending plane, either partially or entirely within the groove, which significantly lowers mechanical strain during bending.

A complementary structural approach places a first connection line directly on the exposed polymer substrate in the bending area and a second connection line above it on an organic planarization layer, with vertical electrical connection between them. This arrangement limits the stress sensitive portion of the electrical path to the mechanically optimized region while the remaining routing is carried out outside the bend. The opening in the intermediate substrate layer extends across all first connection lines so that each conductor benefits from the same stress reduction effect.

Additional layers including a bank layer, spacer, and micro coating layer modify the position of the neutral plane and further reduce strain on the connection lines. The width of the opening is intentionally made greater than the region associated with the minimum curvature radius in order to accommodate variation in the attachment position of back plates during manufacturing. The approach maintains fabrication efficiency by forming the first and second connection lines in the same layers used for existing thin film transistor and pixel electrode structures.

Various embodiments of the present specification are directed to providing a display apparatus in which the occurrence of cracks can be prevented in connection lines within a bending area of a display panel.

Various embodiments of the present specification are also directed to providing a display apparatus in which production energy required for production can be reduced and greenhouse gas emissions can be reduced.

Technical benefits of the present specification are not limited to the above benefits, and other benefits that are not described will be able to be clearly understood by those skilled in the art based on the following description.

According to embodiments of the present specification, there is provided a display apparatus including a substrate including an active area in which an image is displayed and a bending area positioned at one side of the active area and having a curvature, at least one first connection line disposed directly on an upper surface of the substrate in the bending area, a first planarization layer disposed on the first connection line, and at least one second connection line that is disposed on the first planarization layer and connected to the at least one first connection line through at least one the first planarization layer.

According to the embodiments of the present specification, by removing the intermediate substrate layer of the substrate in the minimum curvature radius area of the bending area of the display panel and directly arranging the connection lines on the upper surface of the upper substrate layer of the substrate, it is possible to reduce the tensile stress applied to the connection lines, thereby preventing the occurrence of cracks in the connection lines.

According to the embodiments of the present specification, the production energy required for producing the display apparatus can be reduced due to the low defect rate of the display apparatus caused by the cracks of the bending area, and greenhouse gas emissions can be reduced.

Effects of the present specification are not limited to the above effects, and other effects that are not described will be able to be clearly understood by those skilled in the art based on the above detailed description.

### BRIEF DESCRIPTION OF THE SEVERAL VIEWS OF THE DRAWINGS

FIG. 1 is a plan view of a display apparatus according to one embodiment of the present specification.

FIG. 2 is a cross-sectional view of the display apparatus along line II-II in FIG. 1.

FIG. 3 is a cross-sectional view of the display apparatus along line III-III in FIG. 1.

FIG. 4 is an enlarged view of area IV in FIG. 3.

FIG. 5 is a cross-sectional view of a bent bending area of a display panel according to one embodiment of the present specification.

FIG. 6 is a cross-sectional view showing a portion of the bending area of the display panel according to one embodiment of the present specification.

### DETAILED DESCRIPTION

Advantages and features of the present specification and methods for achieving them will become clear by referencing embodiments described below in detail in conjunction with the accompanying drawings. However, the present specification is not limited to the embodiments disclosed below but will be implemented in various different forms, these embodiments are merely provided to make the disclosure of the present specification complete and fully inform those skilled in the art to which the present specification pertains of the scope of the present specification.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numbers indicate the same components throughout the specification. In addition, in describing the present specification, when it is determined that the detailed description of a related known technology may unnecessarily obscure the gist of the present specification, the detailed description thereof will be omitted. When “comprise,” “have,” “consist of,” or the like described herein are used, other parts may be added unless “only” is used. When a component is expressed in a singular form, it includes a plurality of components unless specifically stated otherwise.

In construing a component, the component is construed as including a margin of error even when there is no separate explicit description related to the margin of error.

When the positional relationship is described, for example, when the positional relationship between two parts is described using “on,” “above,” “under,” “next to,” or the like, one or more other parts may be positioned between the two parts, for example, unless “immediately,” “directly,” or “close to” is used.

When the temporal relationship is described, when the temporal relationship is described using “after,” “subsequently,” “then,” “before,” or the like, it may also include a non-consecutive case unless “immediately” or “directly” is used.

Although terms such as first and second are used to describe various components, these components are not limited by these terms. The terms are only used to distinguish one component from another. Accordingly, a first component described below may be a second component within the technical spirit of the present specification.

In the description of components of the present specification, terms such as “first,” “second,” “A,” “B,” “(a),” “(b),” and the like may be used. The terms are only for the purpose of distinguishing a component from another, and the nature, sequence, order, or the like of the corresponding component is not limited by the terms.

When a certain component is described as being “connected,” “coupled,” “joined,” or “attached” to the other component, the certain component may be connected, coupled, joined, or attached directly to the other component, but it should be understood that another component may be interposed between components that may be indirectly connected, coupled, joined, or attached unless otherwise stated specially.

To further elaborate, as used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The terms "coupled" and "in contact" should be interpreted in the same manner.

When a component or a layer is described as “coming into contact with” or “overlapping” the other component or layer, the component or the layer may come into direct contact with or directly overlap the other component or layer, but it should be understood that another component may be interposed between components that may come into indirect contact with and indirectly overlap each other unless otherwise stated specially.

It should be understood that “at least one” includes any combination of one or more of associated components. For example, “at least one of first, second, and third components” may include not only the first, second, or third component, but also any combination of two or more of the first, second, and third components.

The terms “first direction,” “second direction,” “third direction,” “X-axis direction,” “Y-axis direction,” and “Z-axis direction” should not be construed as merely the geometric relationship in which the relationship therebetween is perpendicular and may refer to a wider directionality within the range in which the configuration of the present specification may act functionally.

Features of various embodiments of the present specification may be coupled or combined partially or entirely, various technological interworking and driving are made possible, and the embodiments may be implemented independently of each other or implemented together in an associated relationship.

Hereinafter, various embodiments of the present specification will be described in detail with reference to the accompanying drawings.

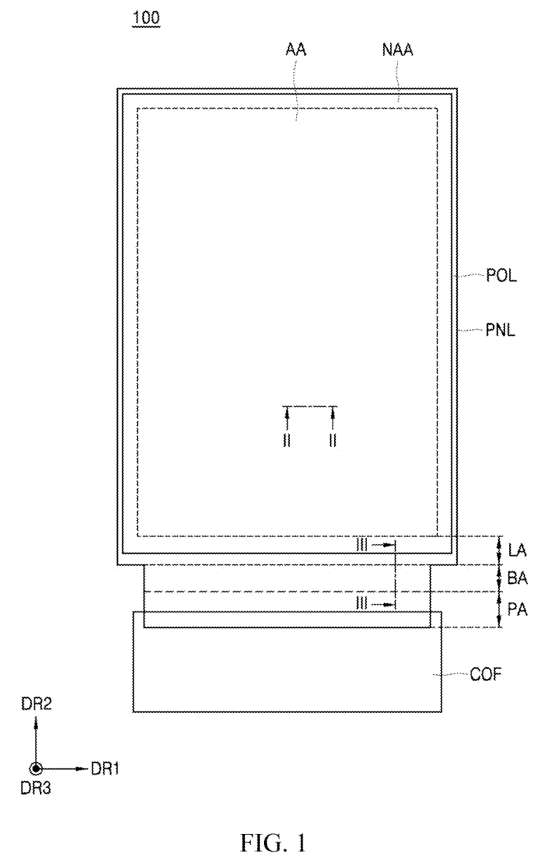

FIG. 1 is a plan view of a display apparatus according to one embodiment of the present specification.

Referring to FIG. 1, a display apparatus 100 according to one embodiment of the present specification may include a display panel PNL, a polarizing plate POL, a chip-on-film COF, a printed circuit board, etc. A data driving chip may be mounted on the chip-on-film COF. A timing controller and a power supplier may be mounted on the printed circuit board.

The display panel PNL may include an active area AA and a non-active area NAA. The active area AA and the non-active area NAA may be areas of a substrate. The active area AA is an area in which an image is implemented. The non-active area NAA is an area in which an image is not implemented and which is positioned outside the active area AA.

The active area AA is an area in which a plurality of pixels are arranged. Each pixel may include a plurality of sub-pixels. The non-active area NAA is an area in which a gate driver and various lines are disposed.

The active area AA includes a plurality of data lines and a plurality of gate lines that are disposed to intersect each other. The plurality of gate lines may extend, for example, in a first direction DR1, and the plurality of data lines may extend, for example, in a second direction DR2.

The non-active area NAA may be disposed to surround the active area AA. For example, when the active area AA has a quadrangular shape, the non-active area NAA may be disposed at upper, lower, left, and right sides of the active area AA.

The gate driver (not shown) may be disposed, for example, in the non-active area NAA positioned at left and right sides of the active area AA.

The non-active area NAA positioned below the active area AA includes a pad area PA in which the chip-on-film COF and the printed circuit board (not shown) are bonded, and a link area LA and a bending area BA that are defined between the link area LA and the pad area PA. The pad area PA may include a plurality of pads to which the chip-on-film COF is connected.

The bending area BA of the non-active area NAA of the display panel PNL may be bent at a predetermined curvature. As the bending area BA of the display panel PNL is bent, the pad area PA of the non-active area NAA may be positioned below the active area AA. Accordingly, a lower bezel area of the display apparatus 100 can be reduced.

A touch sensor may be disposed on the active area AA of the display panel PNL. The touch sensor may be, for example, a mutual capacitance type. The touch sensor may include, for example, a plurality of first touch lines extending in the first direction DR1 and a plurality of second touch lines extending in the second direction DR2.

A polarizing plate POL may be disposed on the display panel PNL to prevent external light reflection.

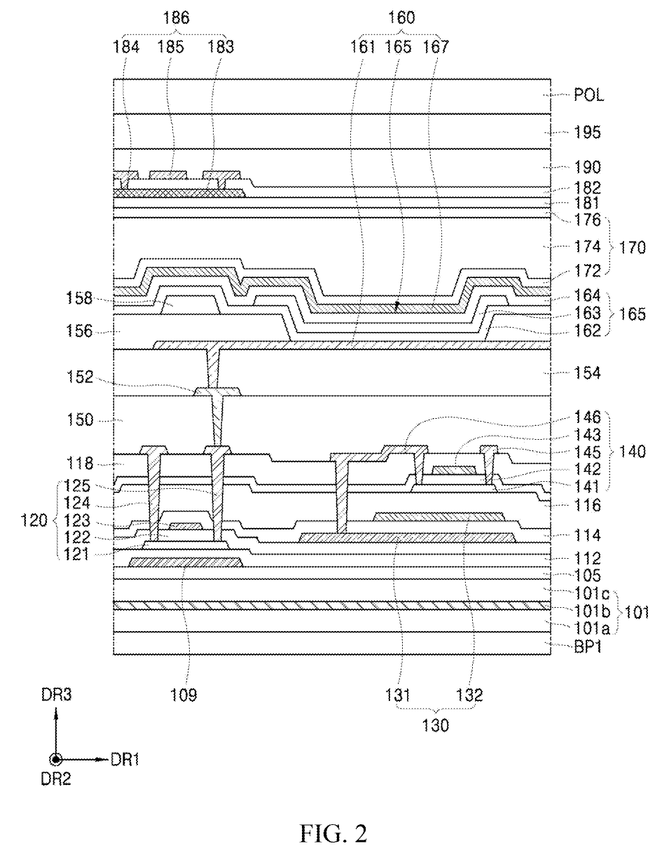

FIG. 2 is a cross-sectional view of the display apparatus along line II-II in FIG. 1. FIG. 2 schematically shows a sub-pixel of the display apparatus according to the embodiment of the present specification.

Referring to FIG. 2, the display apparatus according to an embodiment of the present disclosure may include the display panel PNL, a first back plate BP1 supporting the display panel PNL, and the polarizing plate POL disposed on the display panel PNL. The display panel PNL may include a substrate 101, a first thin film transistor 120, a storage capacitor 130, a second thin film transistor 140, a light-emitting element 160, and a touch sensor 186.

The substrate 101 may include an insulation material. The substrate 101 may include a flexible polymer material. The substrate 101 may have a multilayer structure. For example, the substrate 101 may include a lower substrate layer 101a, an upper substrate layer 101c, an intermediate substrate layer 101b disposed between the lower substrate layer 101a and the upper substrate layer 101c. The lower substrate layer 101a and the upper substrate layer 101c may include, for example, a polymer material such as polyimide (PI) or the like. The intermediate substrate layer 101b may be formed of an inorganic insulation material, such as silicon oxide, silicon nitride, etc. The substrate 101 may be a flexible substrate.

The first back plate BP1 may be disposed below the substrate 101. The first back plate BP1 may be attached to a lower surface of the substrate 101 by an adhesive layer. The first back plate BP1 may be formed of a polymer material, such as polyimide (PI), polyethylene naphthalate (PEN), polyethylene terephthalate (PET), etc.

The first buffer layer 105 may be disposed on the substrate 101. The first buffer layer 105 may be disposed over the entire active area AA of the substrate 101. The first buffer layer 105 may include an insulation material. For example, the first buffer layer 105 may include an inorganic insulation material such as silicon oxide, silicon nitride, or silicon oxynitride. The first buffer layer 105 may have a multilayer structure.

A light-shielding layer 109 may be disposed on the first buffer layer 105. The light-shielding layer 109 may include a metal material. For example, the light-shielding layer 109 may include a metal material such as aluminum (Al), chromium (Cr), copper (Cu), titanium (Ti), molybdenum (Mo), or tungsten (W).

A second buffer layer 112 covering the light-shielding layer 109 may be disposed on the first buffer layer 105. The second buffer layer 112 may include an insulation material. For example, the second buffer layer 112 may include an inorganic insulation material such as silicon oxide, silicon nitride, or silicon oxynitride. The second buffer layer 112 may have a multilayer structure.

A driving circuit may be positioned in each sub-pixel. The driving circuit may generate a driving current provided to the light-emitting element. The driving circuit may be electrically connected to signal lines. For example, the signal lines may include the gate line GL that applies gate signals, the data line DL that applies data signals, and power voltage supply lines that supply power voltages. For example, the driving circuit may include the first thin film transistor 120, the second thin film transistor 140, and the storage capacitor 130.

The first thin film transistor 120 may be electrically connected to the light-emitting element 160. The first thin film transistor 120 may include a first semiconductor pattern 121, a first gate insulating layer 122, a first gate electrode 123, a first source electrode 124, and a first drain electrode 125. The first semiconductor pattern 121 may be disposed on the second buffer layer 112.

The first semiconductor pattern 121 may include a semiconductor material. For example, the first semiconductor pattern 121 may include a polycrystalline semiconductor material. For example, the first semiconductor pattern 121 may include low temperature poly-silicon (LTPS).

The first gate insulating layer 122 may be positioned on the first semiconductor pattern 121. The first gate insulating layer 122 may extend outward from the first semiconductor pattern 121. For example, the first gate insulating layer 122 may extend along an upper surface of the second buffer layer 112. The first gate insulating layer 122 may include an insulation material. For example, the first gate insulating layer 122 may include an inorganic insulation material such as silicon oxide, silicon nitride, and silicon oxynitride.

The first gate electrode 123 may be positioned on the first gate insulating layer 122. The first gate electrode 123 may include a conductive material. For example, the first gate electrode 123 may include a metal material such as aluminum (Al), chromium (Cr), copper (Cu), titanium (Ti), molybdenum (Mo), and tungsten (W). The first gate electrode 123 may be electrically insulated from the first semiconductor pattern 121 by the first gate insulating layer 122. The first gate electrode 123 may overlap a first channel area of the first semiconductor pattern 121.

A first interlayer insulating layer 114 may be positioned on the first gate electrode 123. The first interlayer insulating layer 114 may extend outward from the first gate electrode 123. The first interlayer insulating layer 114 may extend along an upper surface of the first gate insulating layer 122. The first interlayer insulating layer 114 may include an insulation material. For example, the first interlayer insulating layer 114 may include an inorganic insulation material such as silicon oxide, silicon nitride, and silicon oxynitride.

The first source electrode 124 and the first drain electrode 125 may be electrically connected to the first semiconductor layer 121.

The storage capacitor 130 may include a first storage electrode 131 and a second storage electrode 132. For example, the first storage electrode 131 may be positioned on the same layer as the first gate electrode 123. For example, the first storage electrode 131 may be formed of the same material as the first gate electrode 123. The first storage electrode 131 may be disposed near the first gate electrode 123 on the first gate insulating layer 122. The second storage electrode 132 may be disposed to overlap the first storage electrode 131 on the first interlayer insulating layer 114.

The first storage electrode 131 and the second storage electrode 132 may include a conductive material. For example, the first storage electrode 131 and the second storage electrode 132 may include a metal material such as aluminum (Al), chromium (Cr), copper (Cu), titanium (Ti), molybdenum (Mo), and tungsten (W).

A separation insulating layer 116 may cover the second storage electrode 132 and may be disposed on the first interlayer insulating layer 114. The separation insulating layer 116 may include an insulation material. For example, the separation insulating layer 116 may include an inorganic insulation material such as silicon oxide, silicon nitride, and silicon oxynitride. For example, the separation insulating layer 116 may have a multilayer structure including silicon oxide and silicon nitride.

The second thin film transistor 140 may be electrically connected to the first thin film transistor 120. For example, the second thin film transistor 140 may include a second semiconductor pattern 141, a second gate insulating layer 142, a second gate electrode 143, a second source electrode 145, and a second drain electrode 146.

The second semiconductor pattern 141 may include a semiconductor material. The second semiconductor pattern 141 may include a different material from the first semiconductor pattern 121. For example, the second semiconductor pattern 141 may include an oxide semiconductor such as IGZO. The second semiconductor pattern 141 may be positioned on a different layer from the first semiconductor pattern 121. The second semiconductor pattern 141 may be positioned on the separation insulating layer 116. Accordingly, it is possible to prevent damage to the second semiconductor pattern 141 due to a process of forming the first semiconductor pattern 121.

The second gate insulating layer 142 may be disposed on the second semiconductor pattern 141. The second gate insulating layer 142 may extend outward from the second semiconductor pattern 141. For example, the second gate insulating layer 142 may extend along an upper surface of the separation insulating layer 116. The second gate insulating layer 142 may include an insulation material. The second gate insulating layer 142 may include an inorganic insulation material such as silicon oxide, silicon nitride, and silicon oxynitride.

The second gate electrode 143 may be disposed on the second gate insulating layer 142. For example, the second gate electrode 143 may overlap the second channel area of the second semiconductor pattern 141. The second gate electrode 143 may include a conductive material. For example, the second gate electrode 143 may include a metal material such as aluminum (Al), chromium (Cr), copper (Cu), titanium (Ti), molybdenum (Mo), and tungsten (W). For example, the second gate electrode 143 may be formed of the same material as the first gate electrode 123. The second gate electrode 143 may be electrically insulated from the second semiconductor pattern 141 by the second gate insulating layer 142.

A second interlayer insulating layer 118 may be positioned on the second gate electrode 143. The second interlayer insulating layer 118 may extend outward from the second gate electrode 143. The second interlayer insulating layer 118 may extend along an upper surface of the separation insulating layer 116. The second interlayer insulating layer 118 may include an insulation material. For example, the second interlayer insulating layer 118 may include an inorganic insulation material such as silicon oxide, silicon nitride, and silicon oxynitride. For example, the second interlayer insulating layer 118 may have a multilayer structure including silicon oxide and silicon nitride.

The first source electrode 124, the first drain electrode 125, the second source electrode 145, and the second drain electrode 146 may be disposed on the second interlayer insulating layer 118. The first source electrode 124, the first drain electrode 125, the second source electrode 145, and the second drain electrode 146 may include a conductive material. For example, the first source electrode 124, the first drain electrode 125, the second source electrode 145, and the second drain electrode 146 may include a metal material such as aluminum (Al), chromium (Cr), copper (Cu), titanium (Ti), molybdenum (Mo), or tungsten (W). For example, the first source electrode 124, the first drain electrode 125, the second source electrode 145, and the second drain electrode 146 may have a multilayer structure of titanium (Ti)/aluminum (Al)/titanium (Ti).

The first source electrode 124 and the first drain electrode 125 may be electrically connected to the first semiconductor layer 121. For example, the first source electrode 124 and the first drain electrode 125 may be in direct contact with the first semiconductor pattern 121 through contact holes passing through the second interlayer insulating layer 118, the second gate insulating layer 142, the separation insulating layer 116, the first interlayer insulating layer 114, and the first gate insulating layer 122.

The second source electrode 145 and the second drain electrode 146 may be electrically connected to the second semiconductor layer 141. For example, the second source electrode 145 and the second drain electrode 146 may be in direct contact with the second semiconductor pattern 141 through contact holes passing through the second interlayer insulating layer 118 and the second gate insulating layer 142.

The second thin film transistor 140 may be disposed on the storage capacitor 130. For example, the second semiconductor pattern 141 of the second thin film transistor 140 may overlap the storage capacitor 130. Light passing through the substrate 101 and traveling toward the second semiconductor pattern 141 may be blocked by the storage capacitor 130. Accordingly, a change in the characteristics of the second thin film transistor 140 due to external light can be prevented. The storage capacitor 130 may be electrically connected to the second drain electrode 146 of the second thin film transistor 140. For example, the second drain electrode 146 may be in direct contact with the first storage electrode 131 through a contact hole penetrating the second interlayer insulating layer 118, the second gate insulating layer 142, the separation insulating layer 116, and the first interlayer insulating layer 114.

The light-emitting element 160 may be disposed on the driving circuit. For example, the first thin film transistor 120, the second thin film transistor 140, and the storage capacitor 130 of each sub-pixel may be positioned between the substrate 101 and the light-emitting element 160.

A first planarization layer 150 and a second planarization layer 154 may be sequentially stacked between the driving circuit and the light-emitting element 160. The first planarization layer 150 and the second planarization layer 154 may cover a step caused by the driving circuit to provide a flat surface. For example, the first planarization layer 150 and the second planarization layer 154 may include an organic insulation material.

A pixel contact electrode 152 may be disposed on the first planarization layer 150. The light-emitting element 160 may be disposed on the second planarization layer 154. The light-emitting element 160 may include a first electrode 161, a light-emitting layer 165, and a second electrode 167. The light-emitting element 160 may be electrically connected to the first drain electrode 125 of the first thin film transistor 120 through the pixel contact electrode 152. The pixel contact electrode 152 may include a conductive material. For example, the pixel contact electrode 152 may include a metal material such as aluminum (Al), chromium (Cr), copper (Cu), titanium (Ti), molybdenum (Mo), or tungsten (W). For example, the pixel contact electrode 152 may have a multilayer structure of titanium (Ti)/aluminum (Al)/titanium (Ti).

A bank layer 156 may be disposed on the second planarization layer 154. The bank layer 156 may include an organic insulation material. For example, the bank layer 156 may be formed of a photosensitive acryl-based or polyimide-based organic material. The bank layer 156 may cover an edge of the first electrode 161. The bank layer 156 may have an opening that exposes a part of the first electrode 161. The light-emitting layer 165 and the second electrode 167 of the light-emitting element 160 may be stacked on a part of the first electrode 161 exposed by the bank layer 156. A light-emitting area may be defined by the part of the first electrode 161 exposed by the opening of the bank layer 156. The first electrode 161 may include a conductive material. The first electrode 161 may have high reflectivity. For example, the first electrode 161 may include a metal material such as aluminum (Al) or silver (Ag). The first electrode 161 may have a multilayered structure. For example, the first electrode 161 may have a structure in which a metal such as aluminum (Al) or silver (Ag) is disposed between transparent conductive materials such as ITO and IZO.

The light-emitting layer 165 may extend onto the bank layer 156. The light-emitting layer 165 may include a light-emitting material layer 163. For example, the light-emitting material layer 163 may include an organic light-emitting material. The light-emitting layer 165 may have a multilayered structure. For example, the light-emitting layer 165 may include at least one of a first light-emitting common layer 162 positioned between the first electrode 161 and the light-emitting material layer 163 and a second light-emitting common layer 164 positioned between the light-emitting material layer 163 and the second electrode 167. For example, the first light-emitting common layer 162 may include at least one of a hole injection layer (HIL) and a hole transport layer (HTL). The second light-emitting common layer 164 may include at least one of an electron transport layer (ETL) and an electron injection layer (EIL).

For example, when the sub-pixels of each pixel emit light of different colors, the light-emitting material layer 163 of each sub-pixel may be separated from the light-emitting material layer 163 of an adjacent sub-pixel. The light-emitting material layer 163 of each sub-pixel may be formed separately using a fine metal mask (FMM). An end portion of the light-emitting material layer 163 may be positioned on the bank layer 156.

For example, a spacer 158 may be disposed on the bank layer 156. The spacer 158 can prevent damage to the bank layer 156 and the light-emitting material layer 163 through contact with the FMM. For example, the spacer 158 may be formed of a photosensitive acryl-based or polyimide-based organic material. The bank layer 156 and the spacer 158 may be formed simultaneously by a single photolithography process, but are not limited thereto. The bank layer 156 and the spacer 158 may be formed by separate processes, respectively.

The first light-emitting common layer 162 and the second light-emitting common layer 164 of the light-emitting layer 165 may extend along a surface of the bank layer 156. The first light-emitting common layer 162 and the second light-emitting common layer 164 of the light-emitting layer 165 may cover an upper surface and side surfaces of the spacer 158. For example, the first light-emitting common layer 162 and the second light-emitting common layer 164 may be disposed in common in adjacent sub-pixels. For example, each of the first light-emitting common layer 162 and the second light-emitting common layer 164 may be disposed in common in all pixels in the active area AA.

The second electrode 167 may be disposed in common in adjacent sub-pixels. For example, the second electrode 167 may be disposed in common in all pixels in the active area AA. The second electrode 167 may include a conductive material. For example, the second electrode 167 may be a transparent electrode formed of a transparent conductive material such as ITO and IZO.

An encapsulation part 170 may be positioned on the light-emitting element 160. The encapsulation part 170 can prevent damage to the light-emitting elements 160 due to external impacts and moisture. The encapsulation part 170 may have a multilayered structure. For example, the encapsulation part 170 may include a first encapsulation layer 172, a second encapsulation layer 174, and a third encapsulation layer 176 that are sequentially stacked. For example, the first encapsulation layer 172 and the third encapsulation layer 176 may include an inorganic insulation material, and the second encapsulation layer 174 may include an organic insulation material.

The encapsulation part 170 may extend outward from the active area AA. At least one dam structure may be disposed in the non-active area NAA. For example, the dam structure may be positioned on the first planarization layer 150. For example, the dam structure may include at least one organic insulation material. For example, the dam structure may include a first layer formed of the same material as the second planarization layer 154 and a second layer formed of the same material as the bank layer 156. The dam structure may have a closed loop shape surrounding the active area AA of the substrate 101. Since a flow of the second encapsulation layer 174 having fluidity may be blocked by the dam structure, the second encapsulation layer 174 may be positioned on only a portion of the substrate 101 defined by the dam structure. The third encapsulation layer 176 may come into direct contact with the first encapsulation layer 172 outside the second encapsulation layer 174.

The touch sensor 186 may be disposed on the encapsulation part 170. The touch sensor 186 may include a bridge electrode 183, a first touch electrode 184, and a second touch electrode 185. The bridge electrode 183, the first touch electrode 184, and the second touch electrode 185 may be disposed at a position overlapping the bank layer 156. Light emitted from each light-emitting element 160 may not be blocked by the bridge electrode 183, the first touch electrode 184, and the second touch electrode 185.

A touch buffer layer 181 may be disposed between the encapsulation part 170 and the touch sensor 186. The touch buffer layer 181 can prevent the encapsulation part 170 and the light-emitting element 160 from being damaged during the process of forming the first touch electrode 184, the bridge electrode 183, and the second touch electrode 185. For example, an upper surface of the encapsulation part 170 may be covered by the touch buffer layer 181. For example, the touch buffer layer 181 may extend to the non-active area NAA. The touch buffer layer 181 may include an insulation material. For example, the touch buffer layer 181 may include an inorganic insulation material such as silicon oxide, silicon nitride, and silicon oxynitride.

The bridge electrode 183 may be disposed on the touch buffer layer 181. The touch insulating layer 182 may be disposed on the bridge electrode 183. The touch insulating layer 182 may extend along an upper surface of the touch buffer layer 181. For example, the touch insulating layer 182 may extend to the non-active area NAA. For example, the touch insulating layer 182 may include an inorganic insulation material such as silicon oxide, silicon nitride, and silicon oxynitride.

The first touch electrodes 184 and the second touch electrodes 185 may be disposed on the touch insulating layer 182. The bridge electrode 183 may electrically connect adjacent first touch electrodes 184. The adjacent first touch electrodes 184 may be connected to the bridge electrode 183 through contact holes passing through the touch insulating layer 182. The bridge electrode 183 and the first touch electrode 184 may form a first touch electrode line. The second touch electrode 185 may form a second touch electrode line.

The bridge electrode 183, the first touch electrode 184, and the second touch electrode 185 may include a conductive material. For example, the bridge electrode 183, the first touch electrode 184, and the second touch electrode 185 may include a metal material such as aluminum (Al), chromium (Cr), copper (Cu), titanium (Ti), molybdenum (Mo), or tungsten (W). For example, the bridge electrode 183, the first touch electrode 184, and the second touch electrode 185 may have a multilayer structure of titanium (Ti)/aluminum (Al)/titanium (Ti).

A touch protective layer 190 may be disposed on the touch sensor 186. The touch protective layer 190 can prevent damage to the touch sensor 186 due to external impacts and moisture. The touch protective layer 190 may include an insulation material. For example, the touch protective layer 190 may include an organic insulation material. For example, the touch protective layer 190 may be formed of a photosensitive acryl-based or polyimide-based organic material. The touch protective layer 190 may extend to the non-active area NAA.

A cover layer 195 may be disposed on the touch protective layer 190. For example, the cover layer 195 may include an organic insulation material. For example, the cover layer 195 may be formed of an acryl-based, polyimide-based, epoxy-based, or silane-based resin. The touch protective layer 190 may extend to the non-active area NAA. The cover layer 195 may extend to the non-active area NAA.

The polarizing plate POL may be disposed on the cover layer 195. The polarizing plate POL may be attached to an upper surface of the cover layer 195 by an adhesive layer. The polarizing plate POL is a circular polarizing plate and can improve the outdoor visibility of the display apparatus by preventing internal reflection due to external light. The polarizing plate POL may be omitted depending on the configuration of the display panel PNL.

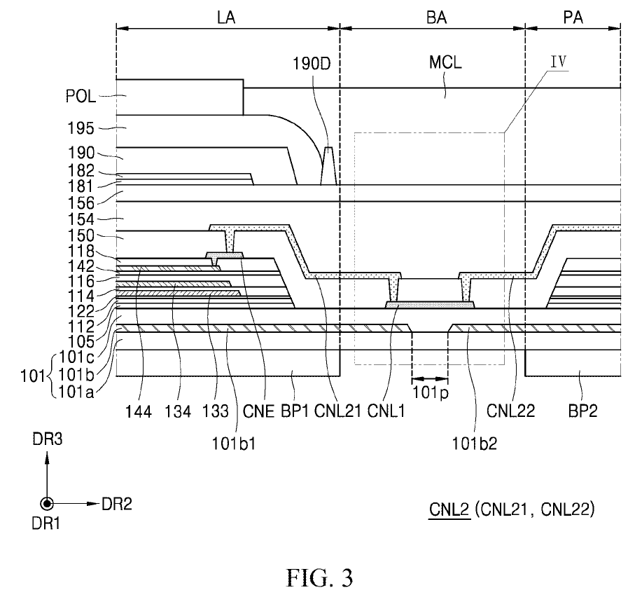

FIG. 3 is a cross-sectional view of the display apparatus along line III-III in FIG. 1. FIG. 3 is a cross-sectional view showing an unfolded state of the bending area BA of the display panel PNL.

Referring to FIG. 3, the first back plate BP1 may be disposed below the substrate 101 in the link area LA of the display panel PNL. A second back plate BP2 may be disposed below the substrate 101 in the pad area PA of the display panel PNL. The first back plate BP1 and the second back plate BP2 may be attached to the lower surface of the substrate 101 by an adhesive layer. The first back plate BP1 and the second back plate BP2 may be formed of a polymer material, such as polyimide (PI), polyethylene naphthalate (PEN), polyethylene terephthalate (PET), etc. A back plate may not be disposed in the bending area BA of the display panel PNL. An area between the first back plate BP1 and the second back plate BP2 may be the bending area BA of the display panel PNL.

The substrate 101 may include the lower substrate layer 101a, the intermediate substrate layer 101b, and the upper substrate layer 101c. The lower substrate layer 101a and the upper substrate layer 101c may be formed of a polymer material. The intermediate substrate layer 101b may be formed of an inorganic material. The intermediate substrate layer 101b of the substrate 101 may have a patterned shape. A portion of the intermediate substrate layer 101b of the substrate 101 may be removed from the bending area BA of the display panel PNL. The intermediate substrate layer 101b of the substrate 101 may include an opening 101p positioned in the bending area BA. The opening 101pof the intermediate substrate layer 101b of the substrate 101 may have a predetermined width in the second direction DR2. In the bending area BA of the display panel PNL, the opening 101p of the intermediate substrate layer 101b of the substrate 101 may extend in the first direction DR1. The opening 101p of the intermediate substrate layer 101b of the substrate 101 may have a predetermined length in the first direction DR1. The intermediate substrate layer 101b of the substrate 101 may include a first intermediate substrate layer 101b1 and a second intermediate substrate layer 101b2 spaced apart from each other by a width of the opening 101p. A thickness of the upper substrate layer 101c may be smaller than a thickness of the lower substrate layer 101a. The upper substrate layer 101c is in contact with the lower substrate layer 101a at the opening 101p.

A first buffer layer 105, a second buffer layer 112, a first gate insulating layer 122, a first interlayer insulating layer 114, a separation insulating layer 116, a second gate insulating layer 142, and a second interlayer insulating layer 118 may be disposed on the substrate 101 in the link area LA and pad area PA of the display panel PNL.

However, the first buffer layer 105, the second buffer layer 112, the first gate insulating layer 122, the first interlayer insulating layer 114, the separation insulating layer 116, the second gate insulating layer 142, and the second interlayer insulating layer 118, which are formed of an inorganic insulation material that is prone to cracking, may not be disposed in the bending area BA of the display panel PNL.

A first signal line 133, a second signal line 134, and a third signal line 144 may be disposed in the link area LA of the display panel PNL. The first signal line 133 may be disposed between the first gate insulating layer 122 and the first interlayer insulating layer 114. The first signal line 133 may be formed in the same layer as the first gate electrode 123 using the same material and the same process. The second signal line 134 may be disposed between the first interlayer insulating layer 114 and the separation insulating layer 116. The second signal line 134 may be formed in the same layer as the first source electrode 124 and the first drain electrode 125 using the same material and the same process. The third signal line 144 may be disposed between the second gate insulating layer 142 and the second interlayer insulating layer 118. The third signal line 144 may be formed in the same layer as the second gate electrode 143 using the same material and the same process.

In addition, a link contact electrode CNE may be disposed on the second interlayer insulating layer 118 in the link area LA of the display panel PNL. The link contact electrode CNE may be formed in the same layer as the second source electrode 145 and the second drain electrode 146 using the same material and the same process.

A first connection line CNL1 may be disposed on the substrate 101 in the bending area BA of the display panel PNL. The first connection line CNL1 may be disposed directly on the upper surface of the substrate 101. The opening 101p of the intermediate substrate layer 101b of the substrate 101 may be disposed below the first connection line CNL1. A portion of the first connection line CNL1 may overlap the opening 101p of the intermediate substrate layer 101b of the substrate 101. The first connection line CNL1 may extend, for example, to a predetermined length in the second direction DR2. The first connection line CNL1 may have a length larger than a width of the opening 101p of the intermediate substrate layer 101b of the substrate 101. The first connection line CNL1 may be formed in the same layer as the second source electrode 145 and the second drain electrode 146 using the same material and the same process.

FIG. 3 shows one first connection line CNL1, but a plurality of first connection lines CNL1 may be disposed on the substrate 101 in the bending area BA of the display panel PNL. The opening 101p of the intermediate substrate layer 101b of the substrate 101 may extend in a direction intersecting the plurality of first connection lines CNL1. For example, the opening 101p of the intermediate substrate layer 101b may be formed in the shape of a line intersecting the plurality of first connection lines CNL1.

The first planarization layer 150 covering the link contact electrode CNE and the first connection line CNL1 may be disposed on the second interlayer insulating layer 118. The first planarization layer 150 extending from the active area AA of the display panel PNL may be disposed continuously in the link area LA, the bending area BA, and the pad area PA of display panel PNL. The first planarization layer 150 may be directly disposed on the upper surface of the substrate 101 in the bending area BA of the display panel PNL.

A second connection line CNL2 may be disposed on the first planarization layer 150 and disposed in the link area LA, the bending area BA, and the pad area PA of the display panel PNL. The second connection line CNL2 may include a first portion CNL21 disposed in the link area LA and the bending area BA of the display panel PNL, and a second portion CNL22 disposed in the bending area BA and the pad area PA of the display panel PNL.

One end of the first portion CNL21 of the second connection line CNL2 may be connected to the link contact electrode CNE in the link area LA, and the other end of the first portion CNL21 of the second connection line CNL2 may be connected to the first connection line CNL1 in the bending area BA. One end of the second portion CNL22 of the second connection line CNL2 may be connected to the first connection line CNL1 in the bending area BA, and the other end of the second portion CNL22 of the second connection line CNL2 may be connected to the pad in the pad area PA. The second connection line CNL2 may be formed in the same layer as the pixel contact electrode 152 using the same material and the same process.

FIG. 3 shows one second connection line CNL2, but a plurality of second connection lines CNL2 may be disposed on the substrate 101 in the bending area BA of the display panel PNL.

The second planarization layer 154 covering the second connection line CNL2 may be disposed on the first planarization layer 150. The second planarization layer 154 extending from the active area AA may be disposed continuously in the link area LA, the bending area BA, and the pad area PA. The second planarization layer 154 can protect the first and second connection lines CNL1 and CNL2 from external impacts and moisture.

The bank layer 156 may be disposed on the second planarization layer 154 in the link area LA, the bending area BA, and the pad area PA of the display panel PNL. The touch buffer layer 181 and the touch insulating layer 182 may be disposed on the bank layer 156 in the link area LA of the display panel PNL. End portions of the touch buffer layer 181 and the touch insulating layer 182 may be positioned within the link area LA. In one embodiment, a spacer 158 may be further disposed on the bank layer 156 in the link area LA, the bending area BA, and the pad area PA of the display panel PNL. The touch buffer layer 181 and the touch insulating layer 182 may be disposed on the spacer 158. The bank layer 156 and the spacer 158 may be disposed in the bending area BA to move a position of a neutral plane in the bending area BA of the display panel PNL upward from the substrate 101 and reduce the tensile stress applied to the first and second connection lines CNL1 and CNL2. The bank layer 156 and the spacer 158 can protect the first and second connection lines CNL1 and CNL2 from external impacts and moisture.

The touch protective layer 190 may be disposed on the touch buffer layer 181 and the touch insulating layer 182. The touch protective layer 190 may cover end portions of the touch buffer layer 181 and the touch insulating layer 182. A partition wall 190D may be disposed on a portion of the bank layer 156. The plurality of partition walls 190D may be disposed in the link area LA, but are not limited thereto. The partition wall 190D may be disposed in the bending area BA. The partition wall 190D may serve as a dam to prevent the organic material forming the cover layer 195 from flowing to the outside of the display panel PNL during the process of forming the cover layer 195 disposed on the touch protective layer 190. The partition wall 190D may have a closed loop shape surrounding the active area AA of the substrate 101. The partition wall 190D may be formed in the same layer as the touch protective layer 190 using the same material and the same process.

The cover layer 195 may be disposed on the touch protective layer 190 in the link area LA of the display panel PNL. The cover layer 195 may come into contact with the partition wall 190D.

The polarizing plate POL may be disposed on the cover layer 195. The polarizing plate POL may be attached to an upper surface of the cover layer 195 by an adhesive layer.

A micro-coating layer MCL may be disposed in the link area LA, the bending area BA, and the pad area PA of the display panel PNL. The micro-coating layer MCL may be disposed on the bank layer 156. The micro-coating layer MCL may be formed of a photocurable resin. For example, the micro-coating layer MCL may be formed of a photocurable acrylic resin. The micro-coating layer MCL may move the position of the neutral plane in the bending area BA upward from the substrate 101 and reduce the tensile stress applied to the first and second connection lines CNL1 and CNL2. The micro-coating layer MCL can protect the first and second connection lines CNL1 and CNL2 from external impacts and moisture.

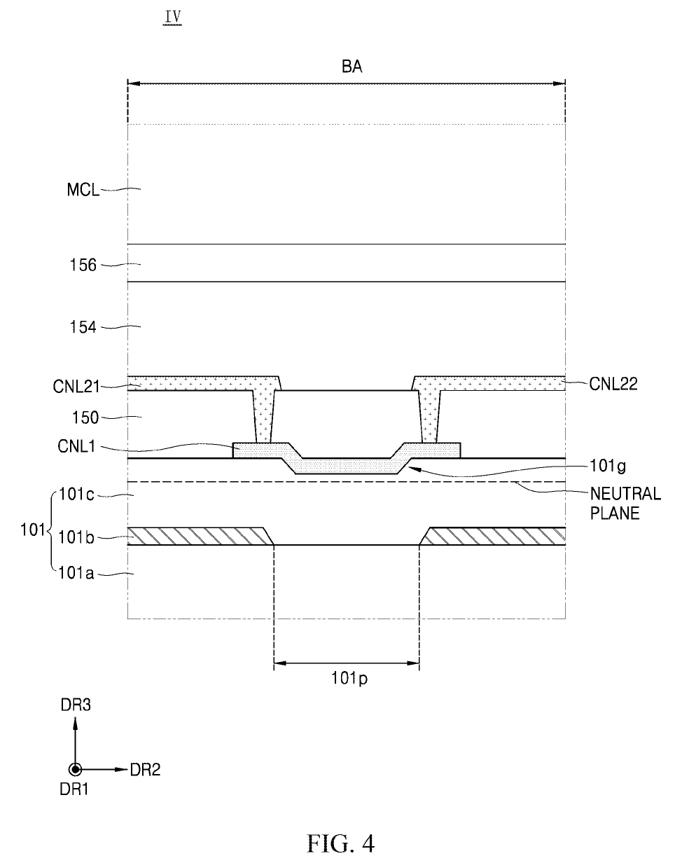

FIG. 4 is an enlarged view of area IV in FIG. 3.

Referring to FIG. 4, the intermediate substrate layer 101b of the substrate 101 may include the opening 101p positioned in the bending area BA of the display panel PNL. The upper substrate layer 101c of the substrate 101 may include a groove 101g at a position corresponding to the opening 101p of the intermediate substrate layer 101b.

In a portion of the bending area BA of the display panel PNL, the first connection line CNL1 may be directly disposed on an upper surface of the upper substrate layer 101c. The first portion CNL21 and the second portion CNL22 of the second connection line CNL2 may pass through the first planarization layer 150 and may be connected to both ends of the first connection line CNL1, respectively.

The first connection line CNL1 may be disposed directly on the upper surface of the upper substrate layer 101c with a length larger than a width of the groove 101g of the upper substrate layer 101c. A portion of the first connection line CNL1 may be disposed within the groove 101g of the upper substrate layer 101c, and the remainder of the first connection line CNL1 may be disposed outside the groove 101g of the upper substrate layer 101c. A middle portion of the first connection line CNL1 may be disposed within the groove 101g of the upper substrate layer 101c, and the end portions of both sides of the first connection line CNL1 may be disposed outside the groove 101g of the upper substrate layer 101c.

In the present embodiment, the neutral plane may be positioned in an upper portion of the upper substrate layer 101c, and instead of using the second connection line CNL2 throughout the entire bending area BA, the first connection line CNL1 may be disposed directly on the upper surface of the upper substrate layer 101c in a portion of the bending area BA, thereby allowing the first connection line CNL1 to be disposed close to the neutral plane and reducing the tensile stress applied to the first connection line CNL1. In addition, by arranging a portion of the first connection line CNL1 in the groove 101g of the upper substrate layer 101c, the portion of the first connection line CNL1 may be positioned closer to the neutral plane, further reducing the tensile stress applied to the portion of the first connection line CNL1.

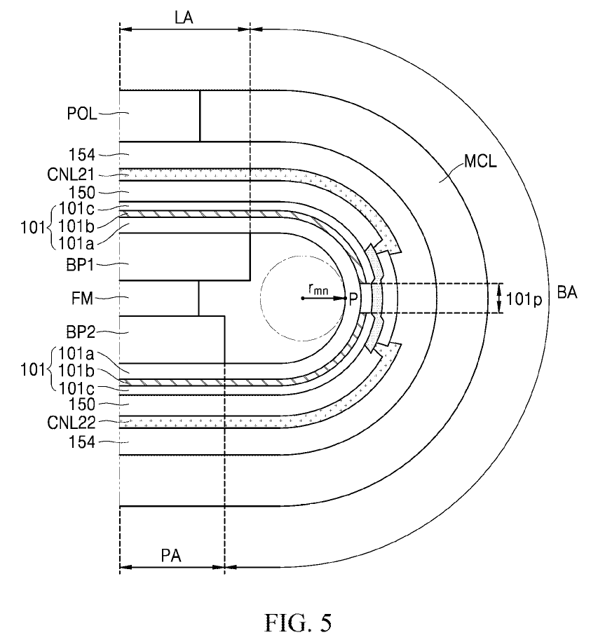

FIG. 5 is a schematic cross-sectional view of a bent bending area of a display panel according to one embodiment of the present specification.

Referring to FIG. 5, the second back plate BP2 may be coupled to the first back plate BP1 by a fixing member FM to maintain the bending area of the display panel in a bent state. A lower surface of the second back plate BP2 and a lower surface of the first back plate BP1 may face each other. The fixing member FM may be, for example, a foam tape.

A curvature of the substrate 101 in the bending area BA of the display panel PNL may vary depending on each position. The substrate 101 may have a small curvature at positions adjacent to the first back plate BP1 and the second back plate BP2, but may have a large curvature at positions far from the first back plate BP1 and the second back plate BP2. The substrate 101 may have a larger curvature radius at positions adjacent to the first back plate BP1 and the second back plate BP2, but may have a smaller curvature radius at positions far from the first back plate BP1 and the second back plate BP2. The greatest tensile stress may be applied to the first connection lines CNL1 in an area in which the curvature of the substrate 101 is greatest, that is, in an area in which the curvature radius thereof is smallest.

In the present embodiment, in order to reduce the maximum tensile stress applied to the first connection lines CNL1, the opening 101p of the intermediate substrate layer 101b of the substrate 101 is designed to be positioned in a portion of the substrate 101 (referred to as a “minimum curvature radius area”) that includes a point (minimum curvature radius point) P at which the substrate 101 has a minimum curvature radius rₘₙ. Accordingly, the groove 101g of the upper substrate layer 101c may also be positioned in the minimum curvature radius area of the substrate 101. Here, the minimum curvature radius area of the substrate 101 may be an area ranging from -15° to +15° with respect to a virtual line connecting the minimum curvature radius point P to the center of curvature. A width of the opening 101p of the intermediate substrate layer 101b of the substrate 101 is preferably larger than the minimum curvature radius area of the substrate 101.

According to the present embodiment, by removing the intermediate substrate layer of the substrate in the minimum radius of curvature area of the bending area of the display panel and directly arranging the first connection lines on the upper surface of the upper substrate layer of the substrate, it is possible to reduce the tensile stress applied to the first connection lines, thereby preventing the occurrence of cracks in the first connection lines.

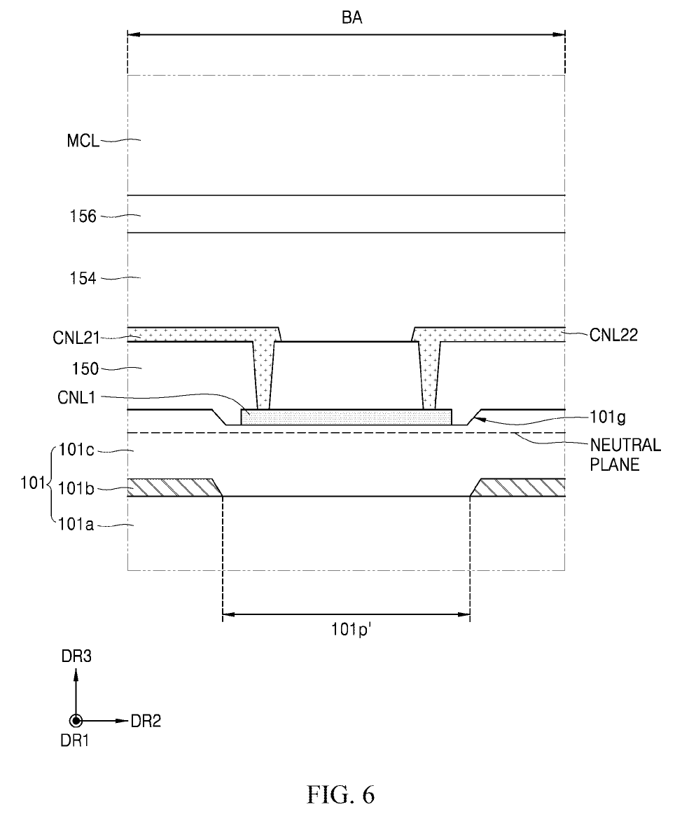

FIG. 6 is a cross-sectional view showing a portion of the bending area of the display panel according to one embodiment of the present specification.

Referring to FIG. 6, the intermediate substrate layer 101b of the substrate 101 may include an opening 101p′ positioned in the bending area BA of the display panel PNL. The upper substrate layer 101c of the substrate 101 may include a groove 101g′ at a position corresponding to the opening 101p′ of the intermediate substrate layer 101b.

In a portion of the bending area BA of the display panel PNL, the first connection line CNL1 may be directly disposed on an upper surface of the upper substrate layer 101c. The first portion CNL21 and the second portion CNL22 of the second connection line CNL2 may pass through the first planarization layer 150 and may be connected to both ends of the first connection line CNL1, respectively.

A width of the opening 101p′ of the intermediate substrate layer 101b of the substrate 101 and a width of the groove 101g′ of the upper substrate layer 101c may be larger than the length of the first connection line CNL1. The first connection line CNL1 may be disposed directly on the upper surface of the upper substrate layer 101c with a length smaller than a width of the groove 101g′ of the upper substrate layer 101c. The entire first connection line CNL1 may be disposed within the groove 101g′ of the upper substrate layer 101c.

In the present embodiment, the neutral plane may be positioned above the upper substrate layer 101c, and instead of using the second connection line CNL2 throughout the entire bending area BA, the first connection line CNL1 may be disposed directly on the upper surface of the upper substrate layer 101c in a portion of the bending area BA, thereby allowing the first connection line CNL1 to be disposed close to the neutral plane and reducing the tensile stress applied to the first connection line CNL1. In addition, by arranging the entire first connection line CNL1 in the groove 101g′ of the upper substrate layer 101c, the entire first connection line CNL1 may be positioned closer to the neutral plane, further reducing the tensile stress applied to the entire first connection line CNL1.

Even in the present embodiment, the opening 101p′ of the intermediate substrate layer 101b of the substrate 101 and the groove 101g′ of the upper substrate layer 101c may also be positioned in the minimum curvature radius area of the substrate 101.

According to the present embodiment, by removing the intermediate substrate layer of the substrate in the minimum radius of curvature area of the bending area of the display panel and directly arranging the first connection lines on the upper surface of the upper substrate layer of the substrate, it is possible to reduce the tensile stress applied to the first connection lines, thereby preventing the occurrence of cracks in the first connection lines.

Meanwhile, when a position of the second back plate BP2 coupled to the first back plate BP1 by the fixing member FM varies due to an error in an attachment process, the minimum curvature radius area of the substrate 101 may change.

According to the present embodiment, since the width of the opening in the intermediate substrate layer of the substrate and the width of the groove in the upper substrate layer of the substrate are formed to be larger than the length of the first connection line, even when the minimum curvature radius of the substrate 101 varies due to an error in the attachment process, the tensile stress applied to the first connection line can be ensured to be reduced.

A display apparatus according to various embodiments of the present specification may be described as follows.

According to embodiments of the present specification, there is provided a display apparatus including a substrate including an active area in which an image is displayed and a bending area positioned at one side of the active area and having a curvature, at least one first connection line disposed directly on an upper surface of the substrate in the bending area, a first planarization layer disposed on the first connection line, and at least one second connection line that is disposed on the first planarization layer and connected to the at least one first connection line through the first planarization layer.

According to some embodiments of the present specification, the at least one second connection line may have a first portion connected to one side of the at least one first connection line and a second portion connected to the other side of the at least one first connection line.

According to some embodiments of the present specification, the substrate may include a lower substrate layer, an intermediate substrate layer, and an upper substrate layer, and the intermediate substrate layer may include an opening disposed below the first connection line.

According to some embodiments of the present specification, the upper substrate layer may include a groove overlapping the opening of the intermediate substrate layer, and a portion of the first connection line may be disposed within the groove of the upper substrate layer, and the remainder of the first connection line may be disposed outside the groove of the upper substrate layer.

According to some embodiments of the present specification, the upper substrate layer may include a groove overlapping the opening of the intermediate substrate layer, and the entire first connection line may be disposed within the groove of the upper substrate layer.

According to some embodiments of the present specification, the opening of the intermediate substrate layer may be provided at a position overlapping a minimum curvature radius area within a bending area of the substrate.

According to some embodiments of the present specification, at least one first connection line may include a plurality of first connection line, and the opening of the intermediate substrate layer may extend in a direction intersecting the plurality of first connection lines.

According to some embodiments of the present specification, the lower substrate layer and the upper substrate layer may be formed of a polymeric material, and the intermediate substrate layer may be formed of an inorganic material.

Although the embodiments of the present specification have been described in more detail with reference to the accompanying drawings, the present specification is not necessarily limited to these embodiments, and various modifications may be carried out without departing from the technical spirit of the present specification. Accordingly, the embodiments disclosed in the present specification are not intended to limit the technical spirit of the present specification, but are intended to describe the technical spirit of the present specification and the scope of the technical spirit of the present specification is not limited by these embodiments. Accordingly, it should be understood that the above-described embodiments are illustrative and not restrictive in all aspects.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a substrate including an active area in which an image is displayed and a bending area positioned at one side of the active area and having a curvature;
at least one first connection line disposed on an upper surface of the substrate in the bending area;
a first planarization layer disposed on the at least one first connection line; and
at least one second connection line that is disposed on the first planarization layer and connected to the at least one first connection line through the first planarization layer.

2. The display apparatus of claim 1, wherein the at least one second connection line has a first portion connected to one side of the at least one first connection line and a second portion connected to the other side of the at least one first connection line.

3. The display apparatus of claim 1, wherein the substrate includes a lower substrate layer, an intermediate substrate layer, and an upper substrate layer, and
wherein the intermediate substrate layer includes an opening disposed below the at least one first connection line.

4. The display apparatus of claim 3, wherein the upper substrate layer includes a groove overlapping the opening of the intermediate substrate layer, and
wherein a portion of at least one the first connection line is disposed within the groove of the upper substrate layer, and the remainder of the at least one first connection line is disposed outside the groove of the upper substrate layer.

5. The display apparatus of claim 3, wherein the upper substrate layer includes a groove overlapping the opening of the intermediate substrate layer, and
wherein the entire at least one first connection line is disposed within the groove of the upper substrate layer.

6. The display apparatus of claim 3, wherein the opening of the intermediate substrate layer is provided at a position overlapping a minimum curvature radius area within the bending area of the substrate.

7. The display apparatus of claim 6, wherein the minimum curvature radius area of the substrate is an area ranging from -15° to +15° with respect to a virtual line connecting a minimum curvature radius point of the substrate to a center of curvature, and
wherein a width of the opening in the intermediate substrate layer is greater than a width corresponding to the minimum curvature radius area of the substrate.

8. The display apparatus of claim 3, wherein the at least one first connection line includes a plurality of first connection lines, and
wherein the opening of the intermediate substrate layer extends in a direction intersecting the plurality of first connection lines.

9. The display apparatus of claim 3, wherein the lower substrate layer and the upper substrate layer are formed of a polymer material, and the intermediate substrate layer is formed of an inorganic material.

10. The display apparatus of claim 1, further comprising a pixel contact electrode disposed on the first planarization layer in the active area.

11. The display apparatus of claim 10, wherein the at least one second connection line is disposed in the same layer as the pixel contact electrode.

12. The display apparatus of claim 1, further comprising a thin film transistor disposed below the first planarization layer in the active area, the thin film transistor including a source electrode and a drain electrode,
wherein the at least one first connection line is disposed in the same layer as the source electrode and the drain electrode of the thin film transistor.

13. The display apparatus of claim 1, wherein the at least one first connection line is disposed directly on the upper surface of the substrate in the bending area.

14. The display apparatus of claim 5, wherein a width of the opening of the intermediate substrate layer is greater than a length of the at least one first connection line.

15. The display apparatus of claim 3, wherein the upper substrate layer is disposed directly on the lower substrate layer at opening.

16. The display apparatus of claim 3, further comprising:
a second planarization layer disposed on the at least one second connection line;
a bank layer disposed on the second planarization layer; and
a micro-coating layer disposed on the bank layer and formed of a photocurable acrylic resin.

17. A display apparatus comprising:
a substrate including a bending area, and comprising a lower substrate layer, an intermediate substrate layer including an opening, and an upper substrate layer in contact with the lower substrate layer at the opening;
a first connection line disposed directly on an upper surface of the upper substrate layer in the bending area;
a first planarization layer disposed on the first connection line; and
a second connection line that is disposed on the first planarization layer and connected to the first connection line through the first planarization layer.

18. The display apparatus of claim 17, wherein the substrate further comprises a link area in a non-active area not displaying an image, and a pad area including a plurality of pads, and the bending area is between the link area and the pad area.

19. The display apparatus of claim 17, wherein the substrate is configured such that a neutral plane of the bending area is in an upper portion of the upper substrate layer.
